(19) United States
(12) Patent Application Publication
(10) Pub. No.: US 2011/0013368 A1
(43) Pub. Date: Jan. 20, 2011

(54) CIRCUIT BOARD MODULE AND ELECTRONIC DEVICE

(75) Inventor: Shotaro Nagaike, Kanagawa (JP)

Correspondence Address: Seed Intellectual Property Law Group PLLC, 701 Fifth Avenue, Suite 5400, Seattle, WA, 98104, US

(73) Assignee: PANASONIC CORPORATION, Osaka (JP)

(21) Appl. No.: 12/863,175

(22) PCT Filed: Mar. 3, 2008
(86) PCT No.: PCT/JP2008/000422

§ 371 Date: Jul. 15, 2010

(30) Foreign Application Priority Data
Jan. 15, 2008 (JP) 2008-005459

(51) Int. Cl. H05K 7/00

(52) U.S. Cl. 361/728

(57) ABSTRACT

There are provided a circuit board module that can ease adverse effect due to radiation developing between a fragile circuit vulnerable to unwanted radiation and other circuits and that can diminish overall radiation to the outside of the module and an electronic device having the circuit board module.

The circuit board module includes a board 1 having a mount surface; a first electronic component and a second electronic component 3 respectively mounted on the mount surface; a first frame element 4 that surrounds the first electronic component 2 and the second electronic component 3, that is mounted on the mount surface, and that exhibits conductivity; a second frame element 5 that surrounds the second electronic component 3, that is mounted on an inside of the first frame element 4 and on the mount surface, and that exhibits conductivity; a first resin portion 6 that is situated between the first frame element 4 and the second frame element 5 and that closely contacts the first electronic component, the mount surface, the first frame element 4, and the second frame element 5; a second resin portion 7 that is situated on an inside of the second frame element 5 and that closely contacts the mount surface of the second electronic component 3 and the second frame element 5; a first cover portion 8 that covers the first electronic component, the second electronic component 3, and the second frame element 5, that exhibits conductivity, and that is connected to the first frame element 4; and a second cover portion 9 that is connected by means of contact points of the second frame element 5 and that covers the second frame element 5.

### TECHNICAL FIELD

The present invention relates to a circuit board module and an electronic device.

### BACKGROUND ART

What is required of an enclosure of a portable electronic device, such as a portable terminal device, is miniaturization, a reduction in thickness, and a reduction in the number of components. In order to meet the demands, a board structure using a low profile, flexible board is adopted as a circuit board to be housed in an enclosure.

As shown in FIG. 5, the board structure 100 has a board 101; a plurality of electronic components 102 mounted on one mount surface 101A of the board 101; a frame element 103 enclosing the respective electronic components 102; and a resin portion 104 that is charged into the inside of the frame element 103, to thus cover the respective electronic components 102, and that closely contacts the mount surface 101A of the board 101.

In such a board structure 100, the electronic components 102 that must be high-frequency shielded are shielded by means of the frame element 103 and a wall portion 105 that partitions the inside of the frame element 103.

Incidentally, the resin portion 104 charged into the inside of the frame element 103 differs from the wall portion 105 in terms of a coefficient of thermal expansion and a coefficient of thermal contraction. Therefore, so-called “sink marks” arise when the charged resin becomes solidified.

As a consequence, “slippage” takes place between the resin portion 104 and the wall portion 105, thereby creating clearance and in turn deteriorating bond strength. This raises a problem of the incapability of maintaining at a predetermined value the strength of the resin portion 104 against external force.

For this reason, a proposed plastic molded semiconductor device (see; for instance, Patent Document 1) has a plurality of through holes or recessed grooves provided on the wall portion in order to assure strength by linking the resin portions separated by the wall portion.

Patent Document 1: JP-A-4-3450

### DISCLOSURE OF THE INVENTION

### Problem that the Invention is to Solve

However, Patent Document 1 is intended for enhancing strength of adhesion between a resin portion and a metal portion, and a shielding characteristic of electronic components to radio communication are not taken into account.

The present invention has been conceived in view of the circumstance and aims at providing a circuit board module capable of easing an adverse effect due to unwanted radiation developing between a fragile circuit vulnerable to unwanted radiation and the other circuits and also capable of diminishing overall radiation to the outside of the module and an electronic device having the circuit board module.

### Means for Solving the Problem

A circuit board module of the present invention has a board having a mount surface; a first electronic component mounted on the mount surface; a second electronic component mounted on the mount surface; a first frame element that surrounds the first electronic component and the second electronic component, that is mounted on the mount surface, and that exhibits conductivity; a second frame element that surrounds the second electronic component, that is mounted on an inside of the first frame element and on the mount surface, and that exhibits conductivity; a first resin portion that is situated between the first frame element and the second frame element and that closely contacts the first electronic component, the mount surface, the first frame element, and the second frame element; a second resin portion that is situated on an inside of the second frame element and that closely contacts the mount surface of the second electronic component and the second frame element; and a first cover portion that covers the first electronic component, the second electronic component, and the second frame element, that exhibits conductivity, and that is electrically connected to the first frame element.

By means of the configuration, adverse effect due to radiation developing between the first electronic component and the second electronic component can be eased, and overall radiation to the outside of the module can be diminished. In particular, when the second electronic component is built from a component having a fragile circuit vulnerable to unwanted radiation, adverse effect due to radiation developing between the first electronic component having a circuit other than the fragile circuit and the second electronic component having the fragile circuit can be diminished, and overall radiation to the outside of the module can be diminished.

The circuit board module of the present invention has a second cover portion that is connected by means of contact points of the second frame element and that covers the second frame element.

By means of the configuration, the second cover portion further covers the second frame element provided in the first frame element covered with the first cover portion. For instance, a fragile circuit, like an RF circuit, provided on an inside of the second cover portion can be electromagnetically shielded more reliably than in a case where the fragile circuit is covered solely with the first cover portion. Specifically, an electromagnetic wave originating outside of the first frame element covered with the first cover portion can be prevented from entering the fragile circuit provided on the inside of the second cover portion, such as an RF circuit. Moreover, it is also possible to effectively prevent unwanted radiation developing from a circuit, other than the fragile circuit, that is on the inside of the first frame element and that is disposed on the outside of the second frame element from imposing adverse effect on the fragile circuit covered with the second cover portion.

In the circuit board module of the present invention, the height from the board to the second cover portion is smaller than the height form the board to the first cover portion.

By means of the configuration, since the height of the second cover portion is smaller than the height from the board to the first cover portion. Therefore, nominal clearance (e.g., of the order of 0.05 mm in a heightwise direction) is created between the first cover portion and the second cover portion. For instance, when experienced physical impact from the outside, the second cover portion does not push the first cover portion high. Specifically, when force is exerted on the first cover portion from the outside, the first cover portion is prevented from being removed, which would otherwise be caused when pushed up by counter reaction against the external force. Therefore, connection between the second cover portion and the second frame element becomes reliable, and connection between the first cover portion and the first frame element also becomes secure.

In the circuit board module of the present invention, a cross sectional profile of the second frame element is a substantially U-shaped geometry.

By means of the configuration, entry of a resin into a substantially U-shaped groove, which would otherwise arise when the resin used for forming the first resin portion and the second resin portion is charged into the inside of the first frame element and the inside of the second frame element, is prevented. Contact points provided in the U-shaped groove of the second frame element can thereby be connected to the second cover portion without being hindered by the resin.

In the circuit board module of the present invention, a bottom surface of the second frame element assuming a substantially U-shaped cross sectional profile is connected to the board, and a relationship represented by Expression (1) stands between a height hᵢₙ of a near center wall, a height hₒᵤₜ of an exterior wall of a wall of the second frame element assuming a substantially U-shaped cross section and the height h₁ from the board to the first cover portion, the height h₂ from the board to the second cover portion.

[Mathematical Expression 1]

h₁>h₂≧hₒᵤₜ>hᵢₙ (1)

By means of the configuration, the height (h₂) from the board to the upper surface of the second cover portion is made greater than the height (hₒᵤₜ) from the board to the exterior wall of the second frame element. When experienced; for instance, physical impact from the outside, the first cover portion thereby first contacts the upper surface of the second cover portion than to the exterior wall of the second frame element. Since the upper surface of the second cover portion is larger than the upper surface of the exterior wall of the second frame element in terms of an area, the first cover portion can be stably held in contact with the upper surface of the second cover portion having a larger area.

An electronic device of the present invention has the aforementioned circuit board module.

### ADVANTAGE OF THE INVENTION

According to the present invention, there can be provided a circuit board module capable of easing an adverse effect due to radiation developing between a fragile circuit vulnerable to unwanted radiation and other circuits and also capable of diminishing overall radiation to the outside of the module and an electronic device having the circuit board module.

### BRIEF DESCRIPTION OF THE DRAWINGS

FIG. 1 It is an exploded perspective view showing a circuit board module of an embodiment of the present invention.

FIG. 2 It is a cross sectional view taken along line II-II shown in FIG. 1.

FIG. 3 It is a cross sectional view of a principal section showing a state of connection between a first frame element and a first cover portion of the circuit board module of the embodiment of the present invention.

FIG. 4 It is a cross sectional view of a principal section showing a connection relationship between a second frame element and a second cover portion of the circuit board module of the embodiment of the present invention.

FIG. 5 It is a cross sectional view of a principal section showing a board structure of a related-art portable terminal device, or the like.

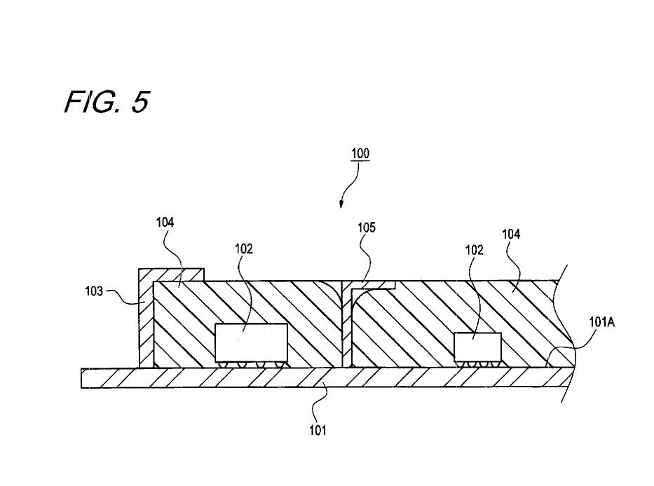

### DESCRIPTIONS OF THE REFERENCE NUMERALS AND SYMBOLS

1 BOARD
2 FIRST ELECTRONIC COMPONENT (DIGITAL CIRCUIT)
3 SECOND ELECTRONIC COMPONENT (FRAGILE CIRCUIT)
4 FIRST FRAME ELEMENT
41 CONTACT POINT
5 SECOND FRAME ELEMENT
51 INTERIOR WALL
51A CONTACT POINT
52 EXTERIOR WALL
53 BOTTOM SURFACE
6 FIRST RESIN PORTION
7 SECOND RESIN PORTION
8 FIRST COVER PORTION
81 HOLE
9 SECOND COVER PORTION
91 HOLE
10 CIRCUIT BOARD MODULE
h1 HEIGHT FROM BOARD TO CEILING OF FIRST COVER PORTION
h2 HEIGHT FROM BOARD TO UPPER SURFACE OF SECOND COVER PORTION
hin HEIGHT OF INTERIOR WALL OF SECOND FRAME ELEMENT
hout HEIGHT OF EXTERIOR WALL OF SECOND FRAME ELEMENT
Δh CLEARANCE

### BEST MODE FOR IMPLEMENTING THE INVENTION

An embodiment of the present invention is hereinbelow described in detail by reference to the accompanying drawings.

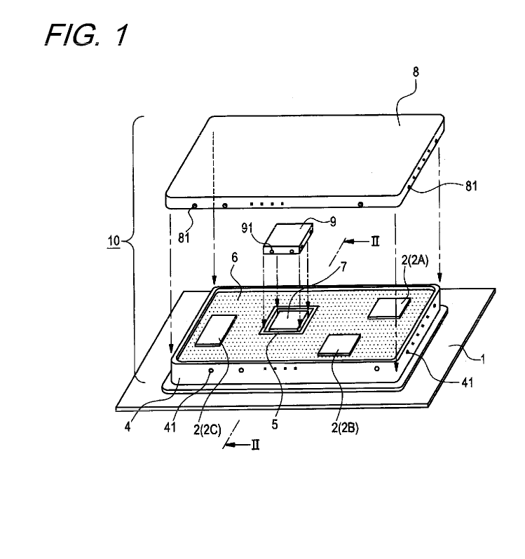

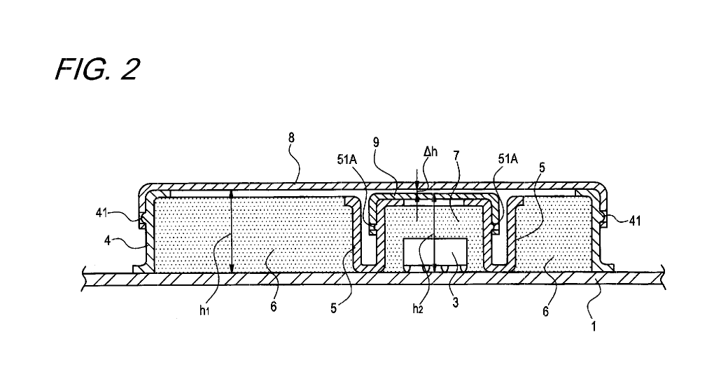

FIG. 1 shows a circuit board module 10 of a first embodiment of the present invention. The circuit board module 10 is set in an enclosure of an unillustrated portable phone that is a kind of electronic device and includes a first board 1, first electronic components 2, a second electronic component 3 (see FIG. 2), a first frame element 4, a second frame element 5, a first resin portion 6, a second resin portion 7, a first cover portion 8, and a second cover portion 9.

The board 1 is formed from a printed board that is thinner than a hitherto-employed printed board, and the circuit board module 10 is set on one surface (a mount surface; namely, an upper surface shown in FIG. 1). An unillustrated large-size display portion built from liquid crystal or organic EL is mounted on the other surface of the board 1 (a lower surface shown in FIG. 1).

The first electronic components 2 are formed from electronic components including; for instance, a digital (electronic) circuit, or the like. The first electronic components 2 are mounted on one surface of the board 1, which corresponds to a mount surface, in an area on the inside of the first frame element 4 corresponding to a large frame and the outside of the second frame element 5 corresponding to a small frame. Electronic components including fragile circuits vulnerable to unwanted radiation are taken as the second electronic component 3 to be described later and electromagnetically shielded and isolated from the first electronic components 2.

As mentioned above, the second electronic components 3 are made up of electronic components including fragile circuits, such as RF circuits, vulnerable to unwanted radiation (hereinafter called “fragile circuits”). The second electronic component 3 is mounted on the inside of the first frame element 4 corresponding to the large frame, on one surface of the board 1 corresponding to a mount surface which is on the same side where the first electronic components 2 are mounted, and further on the inside of the second frame element 5 corresponding to the small frame. When the second electronic components 3 include a fragile circuit, an advantage of the present invention is effectively yielded. However, the fragile circuit being included in the second electronic components 3 is not an indispensable requirement.

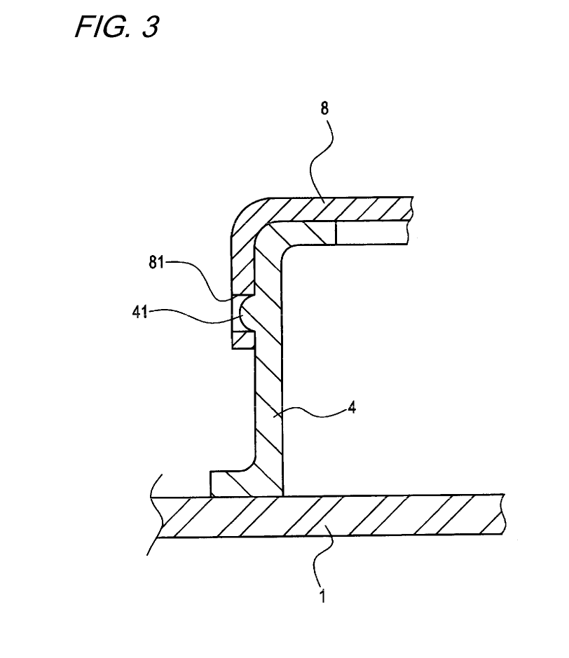

The first frame element 4 makes up a large frame; is mounted on a substantially rectangular mount surface corresponding to one surface of the board 1; and surrounds the first electronic components 2 and the second electronic component 3. In particular, the first frame element 4 of the present invention effects electromagnetic shielding (including high-frequency shielding) along with the first cover portion 8, thereby preventing leakage of electromagnetic radiation from the first frame element 4 to the outside and obstructing entry of unwanted radiation from the outside. To this end, the first frame element 4 is made of a conductive material. Further, as shown in FIG. 3, in order to establish electrical connection with the first frame element, to thus lead an electric potential to a ground of the board 1, and mechanically, removably secure the first frame element, a plurality of contact points 41 are provided along an entire outer periphery of the first frame element 4.

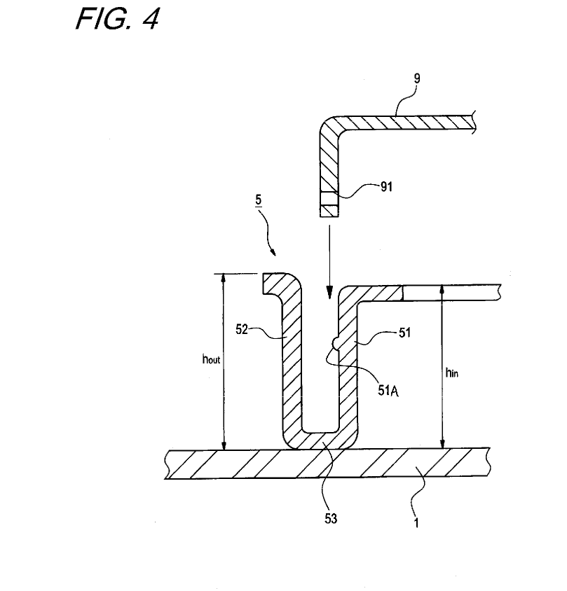

The second frame element 5 is made up of a frame that is smaller than the first frame element 4. In particular, the second frame element is provided on the inside of the first frame element 4 and on the mount surface that is one surface of the board 1, so as to surround the second electronic components 3. The second frame element 5 is formed from a conductive material into an essentially rectangular shape in order to prevent leakage of electromagnetic radiation from the second frame element 5 to the outside and entry of unwanted radiation from the outside, too. Further, as shown in FIG. 4, in order to establish electrical connection with the second cover member 9, to thus lead an electric potential to a ground of the board 1, as will be described alter, and in order to mechanically, removably secure the second frame element, a plurality of contact points 51A are provided along an entire outer periphery of the second frame element 5.

The second frame element 5 of the embodiment includes a near center interior wall 51, an outwardly-oriented exterior wall 52, and a bottom surface 53 that is formed in a planar shape and that connects the interior wall 51 to the exterior wall 52 and also assumes a substantially U-shaped cross sectional profile. The bottom surface 53 is electrically connected to the board 1 and held at the same electric potential level as that of the board 1. Further, correlation expressed by Expression (2) stands between a height hᵢₙ of the interior wall 51 of the second frame element 5 and a height hₒᵤₜ of the exterior wall 52.

[Mathematical Expression 2]

hₒᵤₜ>hᵢₙ (2)

Specifically, the second frame element 5 assumes a substantially U shaped cross section. A U-shaped portion of the second frame element; in other words, an interior of a U-shaped groove on which a protruding contact point 51A is provided on an outer peripheral surface of the interior wall 51, can be configured as a space area. In the present embodiment, in order to prevent intrusion of a resin into the U-shaped groove, a preset amount of; or a predetermined amount of, resin material is charged into the first frame element 4 and the second frame element 5 as mentioned above. Intrusion of the resin into the U-shaped groove is thus prevented, whereby it becomes possible to secure the second cover portion 9 to the contact points 51A of the second frame element 5 without being hindered by the resin. Moreover, a connection with the board 1 can be assured in a stable manner by means of the shape of the essentially-U-shaped flat bottom surface 53.

The first resin portion 6 is mounted on one surface of the board 1 along with the second resin portion 7, whereby an enclosure of an electronic device, such as a portable phone, can assure a certain degree of strength without addition of a metal sheet for reinforcement purpose even when the board 1 that is thinner than a related-art board is used. Put another way, the resin thinly formed on one surface of the thin board 1 makes it possible to reduce the thickness of the enclosure portion of the portable phone that is one kind of electronic device, and a thermosetting resin material is used, as necessary, in the present embodiment. The first resin portion 6 can be hardened without involvement of thermal expansion or contraction when charged over one surface of the board 1 along with the second resin portion 7. Namely, a contrivance to prevent occurrence of warpage in the resin after being thermally set is made.

Of the first resin portion 6 and the second resin portion 7, the first resin portion 6 is interposed between the first frame element 4 and the second frame element 5 so as to closely contact the first electronic components 2, the mount surface of the board 1, the first frame element 4, and the second frame element 5. In the meantime, the second resin portion 7 is provided on the inside of the second frame element 5 so as to closely contact a mount surface of the second electronic component 3 and the second frame element 5.

The first cover portion 8 is arranged so as to physically, integrally cover the first electronic components 2, the second electronic component 3, and the second frame element 5. In particular, the first cover portion 8 is formed from a conductive material along with the first frame element 4 and given an electromagnetic shield function and can prevent leakage of electromagnetic radiation from the first frame element 4 to the outside and entry of unwanted radiation from the outside. Moreover, as shown in FIG. 3, in order to mechanically, removably secure the first frame element 4 and also, simultaneously establish electrical connection with the first frame element 4, a plurality of holes 81 fitting to the corresponding contact points 41 of the first frame element 4 are formed over the entire outer periphery of the first cover portion 8 of the present embodiment. As mentioned previously, the first cover portion 8 is configured so as to become equal in potential to the ground potential of the board 1 by way of the first frame element 4. There is also yielded an advantage of the ability to maintain the ground potential more constantly and enhance the ground.

The second cover portion 9 physically covers the second electronic component 3 and is formed from a conductive material along with the second frame element 5, to thus be given electromagnetic shielding function. The second cover portion 9 can thereby prevent leakage of electromagnetic radiation from the second cover portion 9 to the outside and prevent entry of unwanted radiation from the outside. As mentioned above, the second electronic component 3 that is provided on the inside of the second cover portion 9 and the second frame element 5 is prevented from being subjected to entry of an electromagnetic wave from the outside and emission of the electromagnetic wave to the outside, by means of a double electromagnetic shielding effect yielded by the second cover portion 9 and the second frame element 5 and also yielded by the first cover portion 8 and the first element element 4. Accordingly, when the second electronic component 3 is formed from a fragile circuit, such as an RF circuit, the present invention enables effective prevention of influence of radiation from the first electronic components 2 to the second electronic component 3 and influence of unwanted radiation from the outside.

As shown in FIG. 4, in order to mechanically, removably secure the second frame element 5 and also, simultaneously establish electrical connection with the second frame element, a plurality of holes 91 fitting to the corresponding contact points 51A of the second frame element 5 are formed over the entire outer periphery of the second cover portion 9, as in the case with the first cover portion 8. The second cover portion 9 is configured so as to become equal in electric potential to the ground potential of the board 1 by way of the second frame element 5, and an advantage of the ability to make the ground potential more constantly; namely, to enhance the ground, is yielded as a result of adoption of such a configuration.

Correlation existing between the height of the second cover portion 9 and the first cover portion 8 is a relationship defined by Expression (3). Specifically, the height h₂ from the board 1 to an upper surface of the second cover portion 9 is smaller than the height hᵢ from the board 1 to the ceiling surface of the first cover portion 8.

[Mathematical Expression 3]

h₁>h₂ (3)

Specifically, as shown in FIG. 2, there is assured very small clearance Ah between the ceiling surface of the first cover portion 8 and the upper surface of the second cover portion 9. The height h₂ of the second cover portion 9 is lower than the height h₁ from one surface of the board 1 of the first cover portion 8 to the ceiling surface. By means of this, the second cover portion 9 is prevented from pushing the first cover portion 8 high, and removal of the first cover portion 8, which would otherwise be caused by push, is also prevented. Accordingly, connection of the second cover portion 9 is reliable, and connection of the first cover portion 8 also becomes reliable, either.

A dimensional relationship between the first cover portion 8, the second cover portion 9, and the second frame element 5 is summarized as follows. A relationship represented by Expression (4) stands in connection with Expression (2) representing a relationship between the height of the interior wall 51 of the second frame element 5 and the height hₒᵤₜ of the exterior wall 52 of the same and Expression (3) representing a relationship between the height h₁ from the board 1 to the ceiling surface of the first cover portion 8 and the height h₂ from the board 1 to the upper surface of the second cover portion 9.

[Mathematical Expression 4]

h₁>h₂≧hₒᵤₜ>hᵢₙ (4)

As mentioned above, the present invention provides a configuration such that the height (h₂) from the board 1 to the upper surface of the second cover portion becomes larger than the height (hₒᵤₜ) from the board 1 to the exterior wall 52 of the second frame element 5. By means of such a configuration, for instance, when a physical impact is inflicted on the first cover portion 8 from the outside of the circuit board module 10, the first cover portion 8 contacts first the upper surface of the second cover portion 9 than the exterior wall 52 of the second frame element 5. Since the upper surface of the second cover portion 9 is larger in area than the upper surface of the exterior wall 52 of the second frame element 5, the upper surface of the second cover portion 9 having a large area can stably contact the first cover portion 8. As a consequence, deformation of the first cover portion 8, which would be caused by contact stress, can be made less likely to arise.

The present invention can be practiced in various forms. For instance, the contact points 41A and 51A of the first and second frame elements 4 and 5 can be provided in at least some areas rather than the entire peripheral surface. In the present embodiment, the circuit board module 10 is set in the enclosure of an unillustrated portable phone that is a kind of electronic device. However, the portable phone can be set in various enclosures, such as a straight-type enclosure and a foldable enclosure. In addition to the portable phone, the electronic device in which the circuit board module is to be set includes; for instance, a PDA (Personal Digital Assistant), a PHS (Personal Handyphone System), and various types of electronic devices other than those mentioned.

The present patent application is based on Japanese Patent Application No. 2008-005459 filed on Jan. 15, 2008 in Japan, the entire subject matter of which is incorporated herein by reference.

Although various embodiments of the present invention have been described thus far, the present invention is not limited to matters mentioned in connection with the embodiment and scheduled to be susceptible to alterations or applications contrived by those who are skilled in the art on the basis of descriptions of the specification and well-known techniques. The alterations or applications shall fall within the scope where protection of the present invention is sought.

### INDUSTRIAL APPLICABILITY

The circuit board module of the present invention yields an advantage of the capability of easing an adverse effect due to radiation developing between circuits on a board and diminishing overall radiation to the outside of the module. The circuit board module can be utilized for; for instance, a portable phone, a PDA, and a PHS, and various electronic devices other than those mentioned.

1. A circuit board module comprising:
a board having a mount surface;
a first electronic component mounted on the mount surface;
a second electronic component mounted on the mount surface;
a first frame element that surrounds the first electronic component and the second electronic component, that is mounted on the mount surface, and that exhibits conductivity;
a second frame element that surrounds the second electronic component, that is mounted on an inside of the first frame element and on the mount surface, and that exhibits conductivity;
a first resin portion that is situated between the first frame element and the second frame element and that closely contacts the first electronic component, the mount surface, the first frame element, and the second frame element;
a first cover portion that covers the first electronic component, the second electronic component, and the second frame element, that exhibits conductivity, and that is electrically connected to the first frame element; and
a second resin portion that covers the second frame element, wherein
the first cover portion covers the second cover portions;
the second frame element has an exterior wall contacting the first resin portion and an interior wall situated closer to the second electronic component than to the exterior wall;
a groove is laid between the exterior wall and the interior wall; and
the second cover portion contacts the interior wall in the groove.

2. The circuit board module according to claim 1, further comprising:
a second cover portion that is on an inside of the second frame element and that closely contacts the mount surface of the second electronic component and the second frame element.

3. The circuit board module according to claim 1, wherein a height h₂ from the board to the second cover portion is smaller than a height h₁ from the board to the first cover portion.

4. The circuit board module according to claim 1, wherein a bottom surface of the second frame element assuming a substantially U-shaped cross sectional profile is connected to the board, and a relationship represented by Expression (1) stands between a height h₁ of the interior wall, a height hₒᵤₜ of an exterior wall and the height hᵢₙ from the board to the first cover portion, the height h₂ from the board to the second cover portion:
[Mathematical Expression 1]
h₁>h₂≧hₒᵤₜ>hᵢₙ (1)

5. An electronic device having the circuit board module defined in claim 1.

6. (canceled)
